(19) United States
(12) Patent Application Publication
(10) Pub. No.: US 2026/0213740 A1
(43) Pub. Date: Jul. 23, 2026

(54) Filter and Refresh Circuit Architecture for Electrical Isolators

(71) Applicant: Elevation Microsystems, Inc., Milpitas, CA (US)

(72) Inventors: Celal Avci, Istanbul (TR); Roberto Alini, Dublin, CA (US)

(21) Appl. No.: 19/329,057

(22) Filed: Sep. 15, 2025

Related U.S. Application Data
(60) Provisional application No. 63/747,201, filed on Jan. 20, 2025.

(51) Int. Cl. H03K 5/135; H03K 5/00; H03K 5/06; H03K 5/14; H03K 7/08; H04L 25/02

(52) U.S. Cl. CPC H03K 5/135; H03K 5/06; H03K 5/14; H03K 7/08; H04L 25/0266; H03K 2005/00247

(57) ABSTRACT

In one embodiment, an electrical isolator filter and refresh circuit includes a combined filter and refresh circuit that is configured to filter an input data signal to the electrical isolator and to generate a refresh signal when the input data signal does not change for a predetermined amount of time.

### PRIORITY CLAIM

This application claims the benefit under 35 U.S.C. § 119 of (1) U.S. Provisional Patent Application No. 63/747,201 filed Jan. 20, 2025, which is incorporated by reference herein.

### TECHNICAL FIELD

This application generally relates to a filter and refresh circuit architecture for electrical isolators.

### BACKGROUND

Electrical isolators create electrical separation between two or more components of an electrical system. However, electrical isolators can pass signals or power through the isolated components, for example by using capacitive or inductive methods. For instance, electrical isolators may be used to safely transmit data between electrical components that operate at different voltage domains. Electrical isolators are frequently used in electric vehicles, solar inverters, and industrial automation systems to ensure safe data transmission between voltage domains, among many other applications.

Inductive isolators use a changing magnetic field between two coils to transmit signals across an isolation barrier. Inductive isolators can use transformers to vary the magnetic field, where the strength of the magnetic field depends on the coil structure of the primary and secondary windings, the permittivity of the magnetic core, and the current magnitude.

Capacitive isolators use a changing electric field to transmit signals across an isolation barrier. A capacitive isolator is typically formed by using two capacitor plates with a dielectric material between the plates. The isolation barrier rating is determined by the capacitor plate size, distance between the plates, and the dielectric material.

### BRIEF DESCRIPTION OF THE DRAWINGS

FIG. 1 illustrates an example of a conventional filter and modulator circuit in the context of an electrical isolator.

FIG. 2 illustrates an example of an improved isolator circuit that includes an improved filter and modulation circuit.

FIG. 3 illustrates an example filter and refresh circuit.

FIG. 4 illustrates an example implementation of a filter and counter circuit.

FIG. 5 illustrates an example detailed implementation of a filter and counter circuit.

FIG. 6 illustrates an example modulator circuit.

FIG. 7 illustrates an example detailed implementation of a modulation circuit.

FIG. 8 illustrates an example filter and counter circuit with a self-generated clock.

### DESCRIPTION OF EXAMPLE EMBODIMENTS

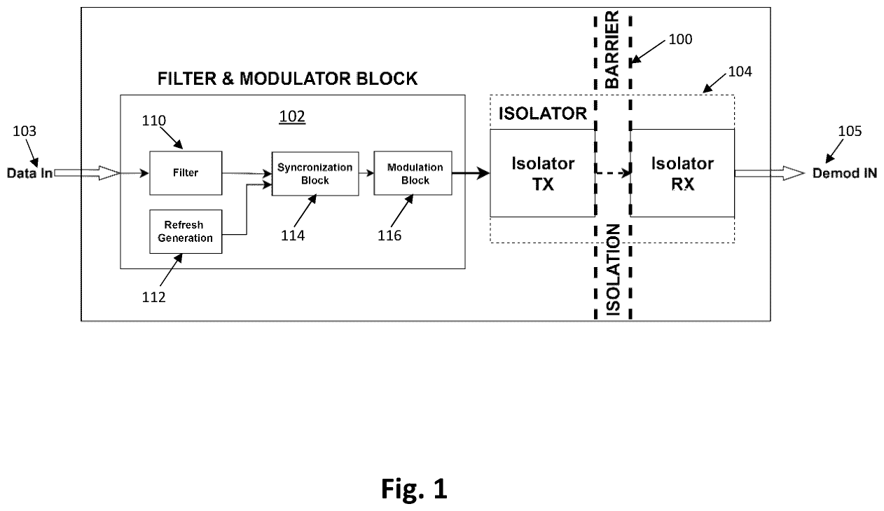

FIG. 1 illustrates an example of a conventional filter and modulator circuit in the context of an electrical isolator. In general, low power electrical isolators mainly consist of edge-based or latched-based communication, which requires a refresh signal to keep input and output data correct in case of a power loss at the receiver. Refresh signals are also used to ensure the correct output is maintained when the input state remains constant for some time. In the example of FIG. 1, a filter and modulation circuit 102 is used to filter and modulate input data for output to isolator 104, which includes a transmitter (Tx) and a receiver (Rx) separated by isolation barrier 100. The output of this overall circuit is the demodulated input 105.

In a conventional filter and modulation circuit, the generating filter 110 and the refresh generator 112 are physically distinct circuits, and therefore require a physically large die area consumption and use additional power. In addition, ensuring synchronization between the filtered data signal and the refresh signal, for example to ensure that the refresh signal does not interfere with the data signal when new data arrives, further complicates the circuit. Maintaining this synchronization requires a precise architectural design and specialized components, which, in turn, increase the complexity, size, and power demands of the electrical isolator. For instance, the example of FIG. 1 illustrates synchronization block 114, which is a dedicated circuit that synchronizes the output from filter 110 and the output from refresh generator 112 and then provides this synchronized output to modulation block 116.

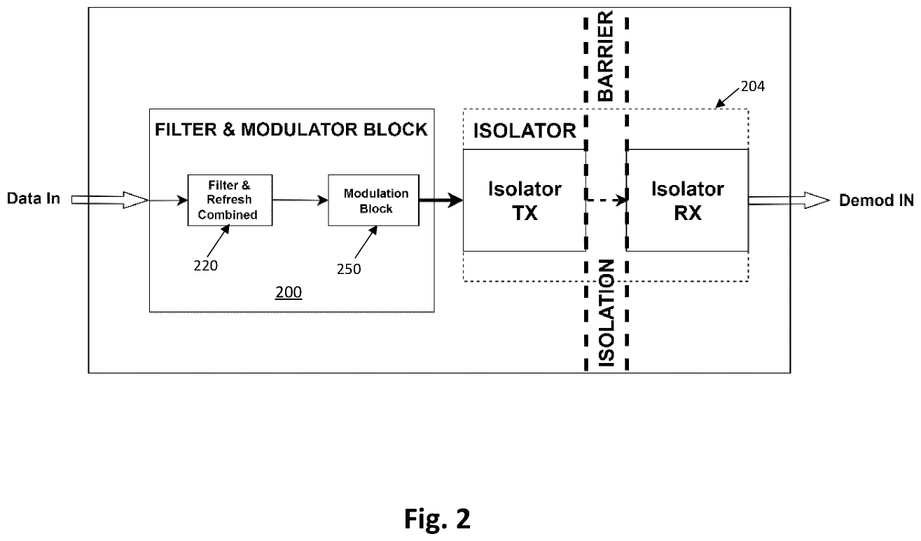

In contrast, FIG. 2 illustrates an example of an improved isolator circuit that includes an improved filter and modulation block 200 that outputs a modulated signal to isolator circuit 204. In the example of FIG. 2, the filter and refresh circuitry 220 is combined into a single circuit block, thereby reducing the size and power requirements of the filter and modulation circuitry. In addition, the improved filter and modulator block 200 does not require a synchronization block, and instead outputs the signal from the combined filter and refresh circuitry 220 directly to modulation block 250, thereby further decreasing the size and complexity of the electrical components in the electrical isolator.

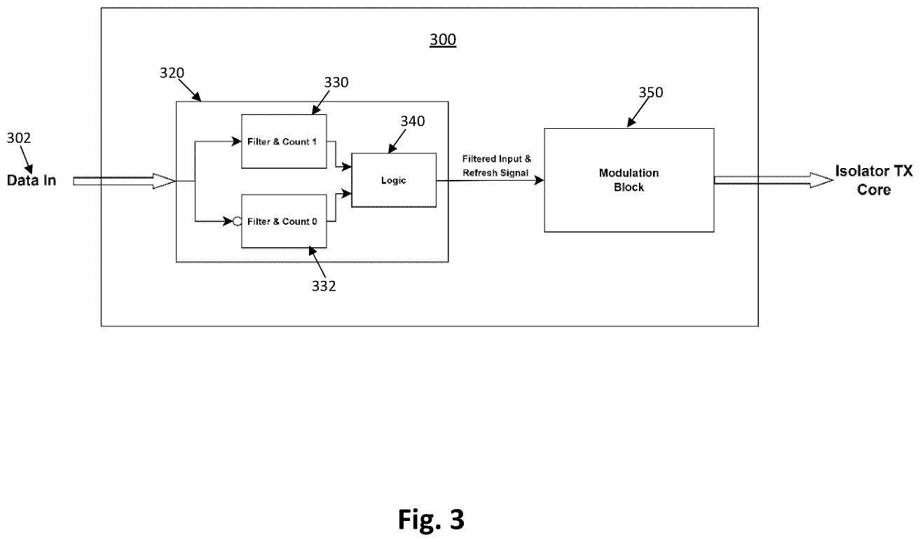

FIG. 3 illustrates an example filter and refresh circuit 320 of the improved filter and modulation block 300. Filter and refresh circuit 320 includes two filter and counter circuits 330 and 332. The input to each filter and counter circuit is based on input data 302 to the overall electrical isolator circuit. In the example of FIG. 3, each filter and counter circuit outputs a filtered signal to logic 340, which outputs a selected filtered input and the refresh signal to the modulation block 350. In the example of FIG. 3, filter and counter circuit 330 receives input data 302 directly, while filter and counter circuit 332 receives the inverse of that input. In the example of FIG. 3, filter and counter circuit 330 maintains the filtering for both “high” and “low” signals (discussed more fully below) as well as the refresh for the high signals (digital 1). Filter and counter circuit 332 likewise maintains the filtering for both high and low signals but maintains the refresh for low signals (digital 0). Such high and low signals may be used in an edge-based isolator, for example.

In particular embodiments, a single filter and count circuit may be used in a isolator circuit, e.g., if there is no need to refresh one of the two signal types. In other embodiments, more than two filter and counter circuits may be used in a single combined filter and refresh circuit, and each filter and counter circuit contains its own filtering and refresh circuitry.

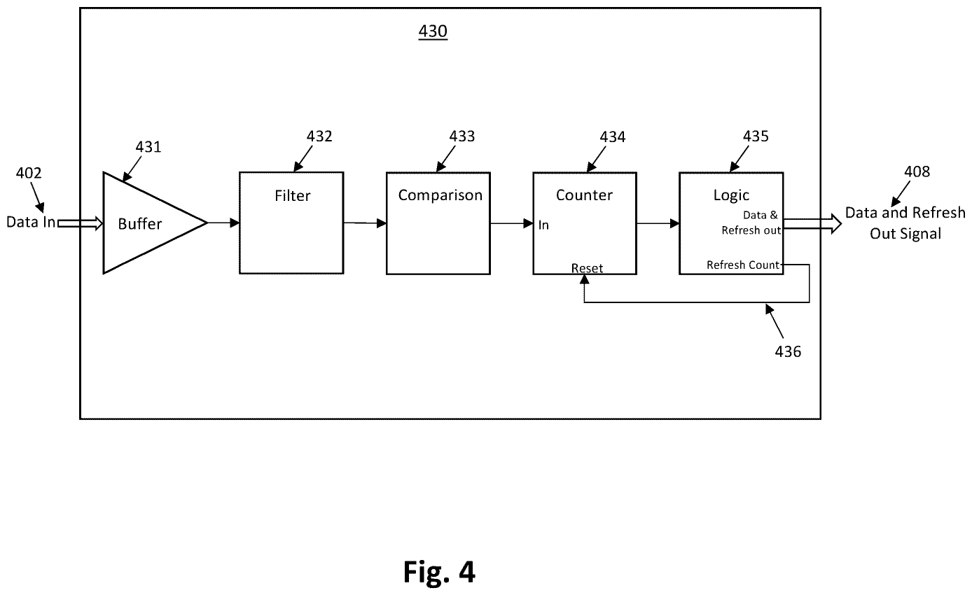

FIG. 4 illustrates an example implementation of a filter and counter circuit block. Filter and counter block 430 in the example of FIG. 4 includes a buffer 431 that receives the input data 402 to the overall electrical isolator circuit. The output of buffer 431 is passed to filter 432, which may be an analog filter or a digital filter, and the filtered output is then passed to comparison circuit 433. The output of comparison circuit 433 is passed to the input terminal of counter circuit 434, which passes its output to logic circuit 435. Logic circuit 435 includes a data and refresh signal output, which passes the data and refresh output signal 408 to the logic circuit 340 of the example of FIG. 3. Logic circuit 435 also includes a refresh counter output 436, which is provided as input to the reset pin of counter circuit 434. These two outputs (data out and the refresh counter that triggers the refresh output) are synchronized because the same counter is used to generate both outputs. Thus, filter and counter circuit 430 combines filtering with a synchronized refresh signal in a single, combined circuit that performs both functions and outputs only either a data signal or a refresh signal without incurring conflict between those two types of output.

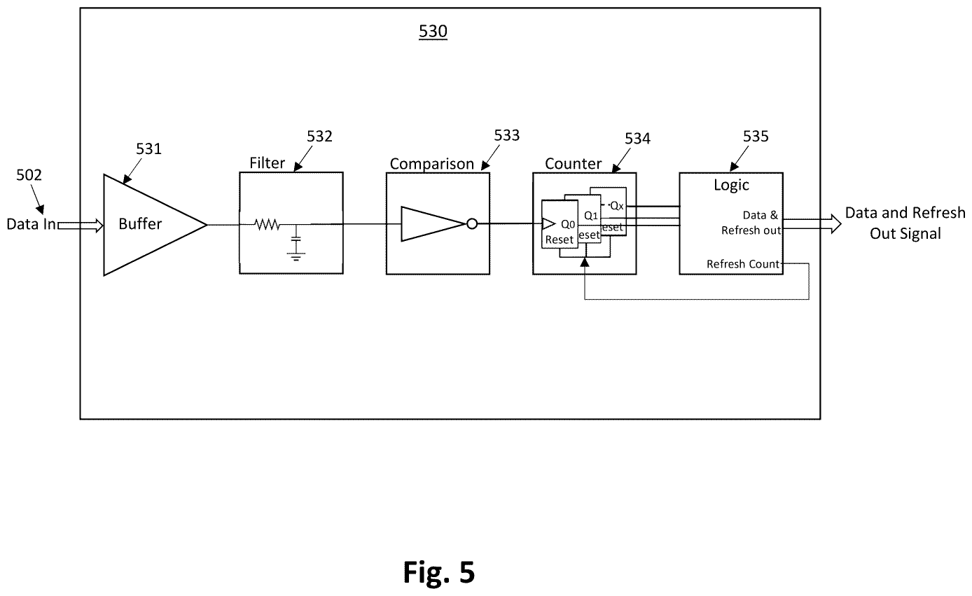

FIG. 5 illustrates an example detailed implementation of the filter and counter block illustrated in FIG. 5. While the example of FIGS. 4 and 5 include a buffer, e.g., buffer circuit 531, the requirement of buffer depends on the drive capability of the previous stage providing the input data, and the buffer can be eliminated if not needed. Also to save area, the filter block 432/532 can also be eliminated, in particular embodiments, if input filtering is not needed. In addition, in some applications, the comparison block 433/533 can also be eliminated to save area.

In the example of FIG. 5, filter 532 is an analog filter, for example any ramp generated signal or any resistive and capacitive (RC) filter. The output of the filter can be sharpened and digitized with a comparator or with an inverter, such as by the invertor of comparison circuit 533.

In the example of FIG. 5, the output of the comparison block is used to trigger the counter. The counter is also be used as a digital filter for the input signal. Any selected counter output value can be used to generate input filtering time. In addition, any value of the counter used for input filtering can also be used to generate a refresh signal, by resetting the counter with the selected value of the counter. For example, if filter 532 is a 50 ns filter and the data output is 250 ns, then counter 534 will count to 5 to create the digital filter. The refresh counter can be, e.g., 10, meaning that when counter 534 counts to 10, then a refresh signal is sent as the output of the logic block, and the counter will reset. The refresh counter can also use the same counter used by the input filter counter. The logic block selects the count value to generate the refresh signal. Also similarly, the logic block selects the count value to generate the filtered input signal. With this approach, the input single is filtered by the counter, and the filtered signal and the refresh signals are synchronized. This architecture therefore eliminates the need for synchronization block which requires accurate timing and adds additional complexity to the electrical isolator system. In other embodiments, the refresh signal period may be determined by the counter's maximum state rather than by a reset signal from logic circuit 535. The reset-signal state need not be the maximum counter state.

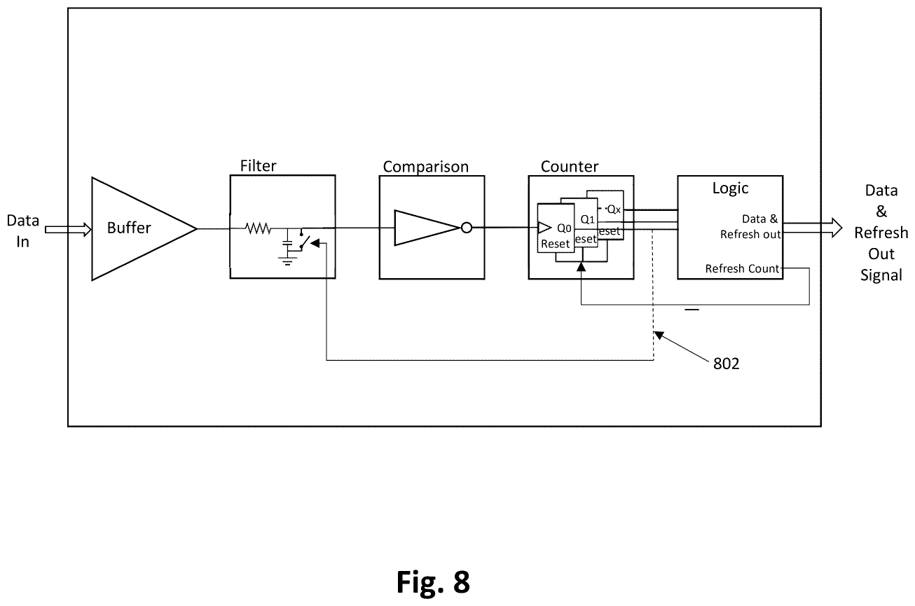

FIG. 8 illustrates an example filter and counter circuit with a self-generated clock. Here, the first counter first bit output (i.e., the least significant bit of the counter output) 802 can be used for resetting both the flip filter and the counter. This reset can be given as a pulse to release the switch after reset. While input data to the filter and counter circuit is high, the clock is generated for the counter. In addition, this self-generated clock is used for the same counter that is generating the refresh signal that eliminates the clock for the refresh. The logic block selects the count value to generate the refresh signal. Also similarly, the logic block selects the count value to generate the filtered input signal. This self-generated clock within the filter and count block additionally reduces the total area of the isolator product by eliminating the clock generation block. Additionally with this approach, the filtered input and the refresh signals are inherently synchronized.

The shared counter illustrated in, e.g., FIG. 8 defines the signal filtering amount for the input signal. Here, the signal filtering amount refers to the amount of time the input signal must maintain its level in order for the filter and counter circuit to output a data pulse. This filtering amount depends on the particulars of the filter circuit and the number of counts required by the logic circuit. For example, suppose an input high (e.g., binary 1) signal arrives. The filter and counter circuit may sample this signal based on the filter characteristics. For example, the input signal may be sampled every 50 ns. If the logic circuit requires that the input signal stay high for a count of, e.g., 5 periods, then the filter and refresh signal will output a data pulse only if the input signal stays high for at least 250(5*50 ) ns. In this example, an input signal that is high only for a duration less than this filtering amount does not result in an output data pulse. After outputting a data pulse, if the input remains high then the filter and counter circuit will periodically output refresh signals (as described herein) until the counter resets.

The shared counter also defines the refresh signal period for the refresh signal, i.e., the amount of time between refresh signals generated and output by the filter and counter circuit. The input signal filtering amount and refresh signal period are defined based on the counter's state. In particular embodiments, the counter state defining the refresh signal period and the counter state defining the filtering amount of input signal are different states of the counter.

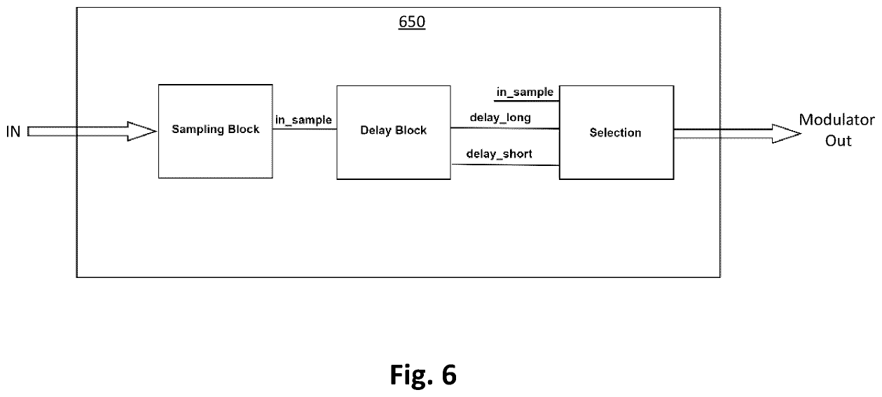

In the example of FIG. 3, the output of each filter and refresh circuit is sent to a logic block 340, which may be an OR gate that selects one of the two output data/refresh signals. The output of logic block 340 is then provided to the modulator. FIG. 6 illustrates an example modulator circuit 650. The modulator includes a sampling block that samples the input of the modulation block. The delay block generates delayed signals (in this example, a short delay signal and a long delay signal), and these delayed signals are selected by selection block which generates the modulated signal using the sampled input and delayed sampled input signals.

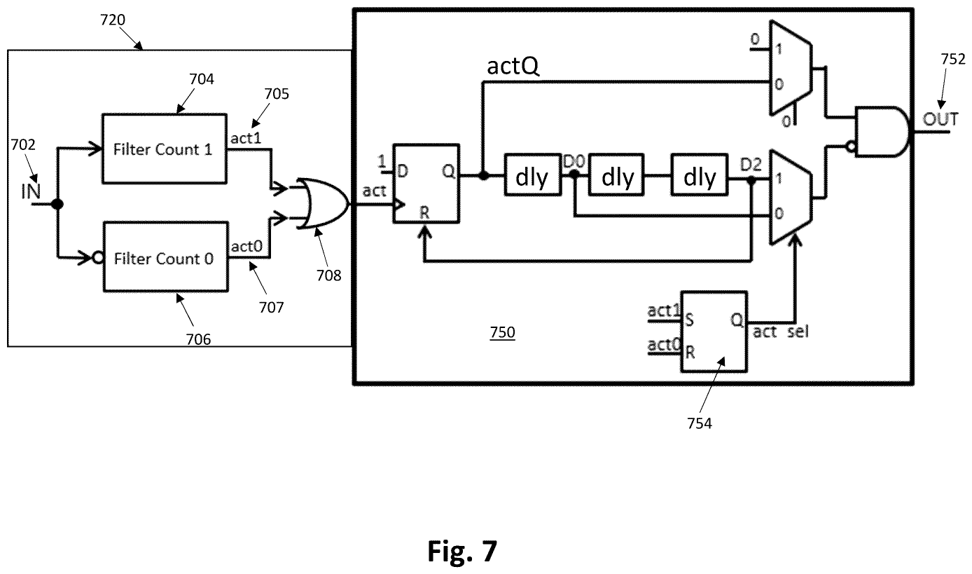

For instance, FIG. 7 illustrates a detailed example implementation of a modulation block. The data input signal 702 is passed to filter and counter circuit 704, and its inverse is passed to filter and counter circuit 706. Each circuit transmits a data signal or a refresh signal based on the data input (i.e., based on whether the input data has changed or has remained the same over a refresh cycle), and this signal is a pulse. OR gate 708 ORs output 707 and 705 from the respective filter and counter circuits and transmits the output to modulation block 750. In modulation block 750, if the output of OR gate 708 is 1, then output 752 goes from low to high to low over a period time specified by the delays in the modulation circuit. For instance, if signal act1 from filter and counter circuit 704 is high (e.g., a binary 1), then the output of SR latch 754 is high, and delay D2 is used, causing output 752 to be high for a period equal to three delays in the delay circuitry. In contrast, if signal act0 from filter and counter circuit 706 is high (e.g., a binary 1), then the output of SR latch 754 is low, and delay D0 is used, causing output 752 to be high for a period equal to 1 delay in the delay circuitry. As a result, output 752 occurs when a change in input data 702 occurs (or when a refresh signal is generated), and the pulse width of output 752 identifies whether the input/refresh data is high (long pulse) or low (short pulse), using the modulation circuit's sampling, selection, and delay circuity.

While the example of FIG. 7 uses a long pulse at the output of the modulator to identify a high input data signal and a short pulse to identify a low input data signal, other embodiments may take an opposite approach and use a short pulse to identify the high signal and a long pulse to identify a low signal. Moreover, each output pulse can have any suitable width, and need not be limited to the exact number of delays shown in the example implementation of FIG. 7.

Using the techniques described herein, low cost and low power communication is reliably maintained over an isolator circuit by using a combined filter and refresh architecture. This combined filter and refresh architecture is provided by inherent refresh generation within the filtering architecture. With this approach, the requirement of separate blocks for filter and refresh functionality is eliminated, which in turn reduces the area and power of the isolator system. Additionally, the inherent synchronization of filtered input and refresh signals eliminates additional synchronization blocks and additional complexity. The proposed architecture not only provides a low power solution that has a reduce physical area, but also maintains a reliable communication over the isolation barrier with the inherent synchronization of data signal and refresh signal.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend.

What is claimed is:

1. An electrical isolator filter and refresh circuit, comprising:
a combined filter and refresh circuit configured to filter an input data signal to the electrical isolator and to generate a refresh signal when the input data signal does not change for a predetermined amount of time.

2. The circuit of claim 1, wherein the combined filter and refresh circuit comprises;
an analog filter configured to filter the input data signal;
a counter configured to filter output from the analog filter to create a filtered data signal; and
circuitry configured to output the filtered data signal or a refresh signal based on a state of the counter.

3. The circuit of claim 2, wherein the circuitry further comprises a self-generating clock.

4. The circuit of claim 2, wherein the counter comprises both a counter for the filtered data signal and a counter for the refresh signal.

5. The circuit of claim 4, wherein the state of the counter further defines (1) a signal filtering amount for the filtered data signal and (2) a refresh signal period for the refresh signal.

6. The circuit of claim 5, wherein the state of the counter for the refresh signal period is different than the state of the counter for the signal filtering amount.

7. The circuit of claim 5, wherein the circuitry is further configured to output a refresh count signal to the counter to reset the counter and define the refresh signal period.

8. The circuit of claim 5, wherein the refresh signal period is defined by a maximum state of the counter.

9. The circuit of claim 5, wherein an output of the counter is coupled to a switch within the analog filter, thereby generating a shared clock for the filtered data signal and the refresh signal.

10. The circuit of claim 2, further comprising a comparison circuit comprising a comparator or an inverter, wherein the comparison circuit is configured to modify the output of the analog filter.

11. The circuit of claim 2, wherein the filtered data signal and the refresh signal comprise a pulse.

12. The circuit of claim 1, further comprising a plurality of combined filter and refresh circuits, wherein a first combined filter and refresh circuit is configured to generate a refresh signal for a high input data signal and a second combined filter and refresh circuit is configured to generate a refresh signal for a low input data signal.

13. The circuit of claim 1, further comprising:
a modulator circuit coupled to the filter and refresh circuit without an intervening synchronization circuit, the modulator circuit configured to modulate an input received from the filter and refresh circuit to provide an output to a transmitter of the electrical isolator.

14. The circuit of claim 13, wherein the modulator circuit comprises:
sampling circuitry configured to sample the input received from the filter and refresh circuit; and
delay circuitry configured to determine, based on the input received from the filter and refresh circuit, a temporal length of the output to the transmitter.

15. The circuit of claim 14, wherein the output to the transmitter comprises a pulse.

16. The circuit of claim 14, wherein the sampling circuitry comprises a latch or a flip flop.

17. The circuit of claim 13, wherein:
the filter and refresh circuit further comprises two combined filter and refresh circuits, each combined filter and refresh circuit providing output to an OR gate; and
the modulator is coupled to the output of the OR gate.

18. The circuit of claim 17, wherein the modulator circuit comprises:
sampling circuitry comprising a latch or a flip flop and configured to sample the input received from the filter and refresh circuit; and
delay circuitry configured to determine, based the output of each combined filter and refresh circuits, a temporal length of the output to the transmitter, wherein the delay circuitry comprises:
a latch or flip flop coupled to the input and refresh circuit and to a delay multiplexer;
a plurality of delay circuits connected in series;
a delay multiplexer coupled to the latch or flip of the delay circuitry and configured to define the temporal length by selecting, based on an output of the latch or flip flop of the delay circuitry, either a first output from a first number of delay circuits or a second output from a second number of delay circuits.

19. The circuit of claim 13, further comprising the transmitter, a receiver, and an isolation barrier electrically isolating the transmitter and the receiver.
